(19) United States
(12) Patent Application Publication
(10) Pub. No.: US 2021/0107449 A1
(43) Pub. Date: Apr. 15, 2021

(54) Cyber-physical energy optimization control system and control method for hybrid electric vehicle

(71) Applicant: BEIJING INSTITUTE OF TECHNOLOGY, Beijing (CN)

(72) Inventors: Chao Yang, Beijing (CN); Weida Wang, Beijing (CN); Kaijia Liu, Beijing (CN); Changle Xiang, Beijing (CN); Muyao Wang, Beijing (CN); Mingjun Zha, Beijing (CN); Weiqi Wang, Beijing (CN)

(73) Assignee: BEIJING INSTITUTE OF TECHNOLOGY

(21) Appl. No.: 17/098,372

(22) Filed: Nov. 14, 2020

(30) Foreign Application Priority Data
Aug. 11, 2020 (CN) 202010802712.0

(51) Int. Cl. B60W 20/11; B60W 20/40; B60W 20/20; G08G 1/01; G01C 21/34; G06Q 10/04

(52) U.S. Cl. CPC B60W 20/11; B60W 20/40; G06Q 10/047; G08G 1/0145; G01C 21/3461; B60W 20/20

(57) ABSTRACT

A cyber-physical energy optimization control system for a hybrid electric vehicle includes an information layer which is configured to realize vehicle and road condition information collection, hybrid control unit (HCU) threshold optimization and threshold wireless update loading, and an optimized object plug-in hybrid electric bus (PHEB) as a physical layer. A cyber-physical energy optimization control method for a hybrid electric vehicle includes steps of collecting a real-time position of an optimized HEV and road slope information of the real-time position, collecting speed information which reflects traffic conditions on a road section to be optimized, constructing a vehicle model virtual operating platform for threshold optimization through the collected information, quickly optimizing related parameters with a help of efficient optimization algorithms, obtaining best results, and finally sending and loading corresponding parameters to a hybrid control unit (HCU) before the optimized vehicle is about to arrive at the optimized road section.

### CROSS REFERENCE OF RELATED APPLICATION

The present invention claims priority under 35 U.S.C. 119(a-d) to CN 202010802712.0, filed Aug. 11, 2020.

### BACKGROUND OF THE PRESENT INVENTION

### Field of Invention

The present invention relates to the field of vehicle control technology, and more particularly to a cyber-physical energy optimization control system and control method for a hybrid electric vehicle.

### Description of Related Arts

With the increasingly severe problems such as air pollution and fuel shortage, traditional cars, which produce a large amount of exhaust gas and have a low energy conversion rate during driving, are increasingly unable to meet social needs. In contrast, due to the special powertrain structure, hybrid electric vehicles (HEVs) are increasingly becoming an ideal means of transportation. In general, a HEV includes one or more motors as power units besides an engine for driving the vehicle together. Due to the introduction of the motors, the demand from the HEV for non-renewable and non-clean energy such as oil or natural gas is directly reduced. Moreover, with the help of the motors, the engine, as a non-linear device, is able to better adjust its real-time operating points, and to output power in a highly efficient state as much as possible. As a result, the energy conversion efficiency of the engine has also been greatly improved.

In order to achieve the above objectives under the premise of ensuring the power demand of the HEV, it is necessary to establish a control method for carrying out a reasonable task allocation to different power units. But the “reliability” here needs to be based on the hybrid control unit (HCU) having appropriate parameters. Therefore, in order to make the HEV achieve good fuel economy, relevant parameters need to be optimized.

FIG. 1 shows an existing energy management strategy optimization process for improving the fuel economy of the coaxial parallel HEV, wherein the HEV uses a rule-based method to realize the torque distribution of the internal powertrain of the HEV. The method requires less computational load, so it is able to realize real-time torque distribution calculation in the current HCU chip, and to be widely used in other practical control problems. The most critical part of rule-based control is the rule base, which is expressed in the form of “If Input is X, Then Output is Y”, directly affecting the mapping relationship between input and output of the HCU. It is able to be known from FIG. 1 that in this method, two inputs of the HCU in the HEV are respectively the state of charge (SOC) of battery and the demand torque T_{d} of the HEV, and two outputs of the HCU are the torques that the engine and the motor need to provide respectively, namely, Tₑ and Tₘ. Take an example of the vehicle powertrain control process to explain the rule control: if SOC>X₁, T_{d}>X₂, Then Tₑ=a (here, a is a preset constant), Tₘ=T_{d}−Tₑ, which means that when two inputs of the HCU meet the above conditions, corresponding control commands are generated for the engine and the motor according to the internal preset rule base of the HCU, so as to meet the power demand of the HEV for normal driving. Meanwhile, it is able to be seen from the rule statement that the thresholds X₁ and X₂ will directly affect the effect of the HCU, that is, determine how to direct different power sources to work in different state. Since the energy conversion efficiency of the powertrain, especially the engine, is directly affected by its actual working state, if it is able to be operated in an ideal state through software control, the fuel economy of the vehicle will be greatly improved. For this purpose, at present, it is common to optimize the rule-based threshold of the HCU to achieve energy saving and consumption reduction of the HEV.

In this study, the HEV whose HCU threshold is optimized is usually a plug-in hybrid electric bus (PHEB) with a fixed driving route, and the reason is determined by the optimization method of the threshold. The optimization method includes steps of constructing a virtual operating scene with the collected historical driving condition data of the HEV, and then combining the optimization algorithm to select the optimal threshold, and finally applying the optimized thresholds to the actual vehicle control. The reason for carrying out these steps is the optimality of the threshold depends on the specific working conditions. If the road conditions change significantly, the previously optimized threshold will greatly reduce the effect of improving the fuel economy of the HEV. In addition, the process of parameter optimization is complex, so the time-consuming optimization would be meaningless if HEV travelled this route only once.

However, it is able to be known from the characteristic that the bus drives frequently on the fixed route, it is very meaningful to optimize its HCU thresholds. Moreover, in the process of collecting bus driving condition data, since the road slope is fixed, only the bus speed trajectory which reflects the traffic condition needs to be collected for completing the preparation of the materials required to build the above virtual operating scene. The role of these data in simulation optimization is mainly to calculate the changes in the required torque Td of the vehicle in different times through a fixed calculation method.

Combined with a simulation model, the optimization process of the above threshold is achieved, which comprises steps of:

(1) measuring and recording a slope and a speed change trajectory of an optimized road section with the help of the on-board electronic level instrument and the controller area network (CAN) card;

(2) constructing a virtual operating scene for threshold optimization with the collected historical driving condition data of the HEV, and then combining the optimization algorithm which is represented by genetic algorithm to select the optimal threshold, wherein the algorithm, a relationship, between the fuel consumption of the vehicle controlled by HCU loaded with thresholds and the fitness function for evaluating the performance of this value, is built; the lower the fuel consumption, the higher the fitness function value, thus the direction of threshold evolution is obtained;

(3) obtaining the best threshold for the road condition through iterative optimization, and then repeating the step (2) under different vehicle speed trajectories which represent different traffic flow conditions, and finally obtaining a threshold for better fuel economy in a variety of operating conditions (as mentioned above, the performance of the threshold is very dependent on its actual optimization environment, but in actual conditions, no working conditions at two moments are exactly the same; and therefore, in order to ensure that the optimized threshold is able to maintain the great fuel economy of the vehicle in different scenes, the comprehensive fuel consumption under various conditions is regarded as the evaluation standard of the threshold); and

(4) manually loading the optimized threshold into the HCU of the actual bus to reduce its fuel consumption.

The above technology has some shortcomings as follows.

(1) In the prior art, it is necessary to manually collect the working condition data for threshold optimization of the HCU, and then perform offline optimization, and finally load the optimized data into the HCU of the actual bus by manual means. This method has cumbersome steps, requires human intervention, and has low efficiency.

(2) Due to the aforementioned complexity of changing the HCU threshold of the bus, it is impossible to update the threshold in real time according to varying road conditions. The prior art is able to only adopt a compromise solution that optimizes a large amount of road condition data in advance in exchange for energy management strategies to achieve better results in different environments. This solution not only causes a heavy computing load, but the obtained strategy generally is unable to make the fuel economy of the vehicle reaches the optimal under specific conditions (The reason is that the result is a compromise value after considering different working conditions, rather than the best threshold selection for this kind of working condition).

(3) In the process of completing this kind of parameter optimization through the optimization algorithm represented by genetic algorithm, there are problems that the optimization speed is slow and it is easy to fall into local optimum, which need to be solved.

### SUMMARY OF THE PRESENT INVENTION

The present invention provides a cyber-physical energy optimization control system and a control method for a hybrid electric vehicle (HEV). Compared with the cumbersome operation process in the traditional method, the present invention greatly reduces the labor cost in the parameter optimization process due to the reasonable use of wireless communication technology, and at the same time creates the possibility to adjust the HCU threshold according to road conditions in time, thus improving the fuel economy of the HEV. Moreover, this kind of cyber-physical optimization architecture also avoids improving the adaptability of the HCU in different environments with the help of huge traffic data, directly reducing the time cost of optimization operations. The present invention adopts the firework algorithm with better optimization effect to optimize the HCU threshold, which greatly accelerates the optimization speed and effectively improves the optimality of obtaining the threshold.

To achieve the above object, the present invention adopts technical solutions as follows.

A cyber-physical energy optimization control system for a hybrid electric vehicle (HEV) comprises an information layer which is configured to realize vehicle and road condition information collection, hybrid control unit (HCU) threshold optimization and threshold wireless update loading, and an optimized object PHEB as a physical layer, wherein:

the information layer comprises:
a global positioning system (GPS) and a geographic information system (GIS) configured to detect a real-time position of a vehicle and a road slope of the real-time position;
a traffic flow condition acquisition device which comprises multiple roadside speed detection cameras and multiple vehicles with a same route as an optimized vehicle, wherein the traffic flow condition acquisition device is configured to collect vehicle speed information which reflects traffic conditions; and
a remote monitoring center which is configured to collect information from the GPS or the GIS and the traffic flow condition acquisition device on a road section to be optimized for constructing a vehicle model virtual operating platform for threshold optimization, and then quickly optimize thresholds with the help of efficient optimization algorithms, and then obtain the best results, and then send and load the optimized thresholds to a hybrid control unit (HCU) before the optimized vehicle is about to arrive at the optimized road section.

A cyber-physical energy optimization control method for a hybrid electric vehicle (HEV) comprises steps of:

collecting a real-time position of an optimized HEV and road slope information of the real-time position, collecting speed information which reflects traffic conditions on a road section to be optimized, constructing a vehicle model virtual operating platform for threshold optimization through the collected information, quickly optimizing hybrid control unit (HCU) thresholds with a help of efficient optimization algorithms, obtaining best results, and finally sending and loading the optimized HCU thresholds to the HCU before the optimized vehicle is about to arrive at the optimized road section.

Preferably, the threshold optimization is achieved by firework algorithm. Of course, the firework algorithm is able to be replaced with other efficient optimization algorithms, as long as the other efficient optimization algorithms are able to obtain better HCU parameters to improve the fuel economy of the HEV in a short time.

The rule-based method is able to be replaced with fuzzy control in the present invention. Both of the rule-based method and the fuzzy method have the good real-time performance. While using the fuzzy method, most of the optimized parameters are the membership functions in the fuzzy method, so as to establish a reasonable correspondence between the input and the output of the HCU.

The present invention has technical effects as follows.

The establishment of cyber-physical system brings certain advantages:

The PHEB under the cyber-physical system is able to obtain more real-time and accurate information about the working conditions of the road section to be optimized with the help of GIS, GPS and traffic flow condition acquisition device. Subsequently, the working conditions are used to construct a virtual operating scene for cloud optimization of HCU thresholds, and the final optimization results are loaded into the HCU of the actual vehicle via wireless communication. Compared with the prior art, the optimization of HCU parameters is more real-time, convenient and efficient.

Due to the advantage of the technology described above, the threshold optimization of the HCU no longer requires huge historical working condition data, but only requires the condition information of road to be optimized. This change not only reduces the amount of calculation in the optimization process, but also makes the optimized parameters more targeted, thus better improving the fuel economy of the vehicle.

Compared with other algorithms, the firework algorithm has its own optimization characteristics as follows.

In the process of optimization, the firework algorithm follows the principle of key search in high-probability areas and fast search in low-probability areas, and is able to efficiently search the locations of the whole area with limited computing power and computing time. Therefore, it has stronger optimization capabilities than traditional algorithms such as genetic algorithm.

### BRIEF DESCRIPTION OF THE DRAWINGS

FIG. 1 shows an existing energy management strategy optimization process.

FIG. 2 shows a cyber-physical energy optimization control system provided by the present invention.

FIG. 3 is a structural diagram of a powertrain of a plug-in hybrid electric bus (PHEB) provided by the present invention.

FIG. 4 shows a control logic of a hybrid control unit (HCU) provided by the present invention.

FIG. 5 shows a HCU threshold optimization process based on firework algorithm provided by the present invention.

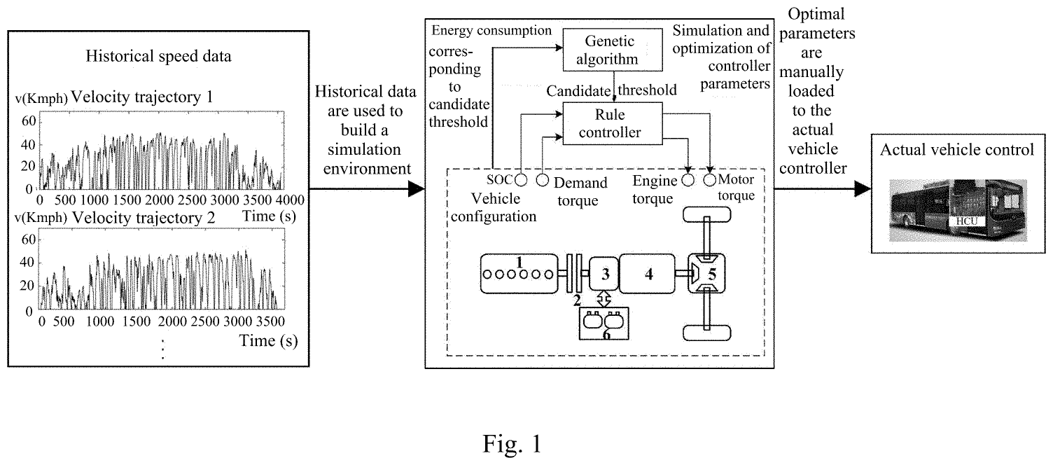

### DETAILED DESCRIPTION OF THE PREFERRED EMBODIMENT

The specific technical scheme of the present invention is explained in combination with the embodiment as follows.

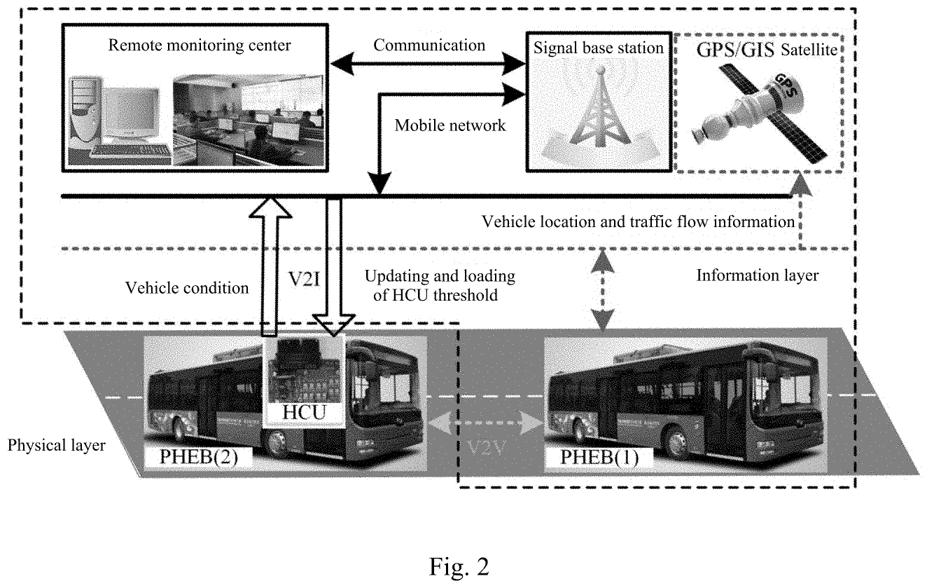

The present embodiment intends to propose an efficient cyber-physical energy optimization control method for a plug-in hybrid electric bus (PHEB) with the help of the currently rapidly developing intelligent network technologies including vehicle-to-vehicle (V2V) and vehicle-to-infrastructure (V2I). As shown in FIG. 2, a cyber-physical energy optimization control system for a hybrid electric vehicle (HEV) comprises an information layer which is able to realize vehicle and road condition information collection, hybrid control unit (HCU) threshold optimization and threshold wireless update loading, and an optimized object PHEB as a physical layer, wherein main components and functions of the information layer are as follows:

a global positioning system (GPS) and a geographic information system (GIS) configured to detect a real-time position of a vehicle and a road slope of the real-time position;

a traffic flow condition acquisition device which comprises multiple roadside speed detection cameras and multiple vehicles with a same route as an optimized vehicle (namely, multiple buses with a same route as the optimized PHEB in FIG. 2), wherein the traffic flow condition acquisition device is configured to collect vehicle speed information which reflects traffic conditions; and

a remote monitoring center which is configured to collect the above two types of information on a road section to be optimized for constructing a vehicle model virtual operating platform for threshold optimization, and then quickly optimize related parameters with the help of efficient optimization algorithms, and then obtain the best results, and then send and load HCU thresholds to a HCU before the optimized vehicle is about to arrive at the optimized road section.

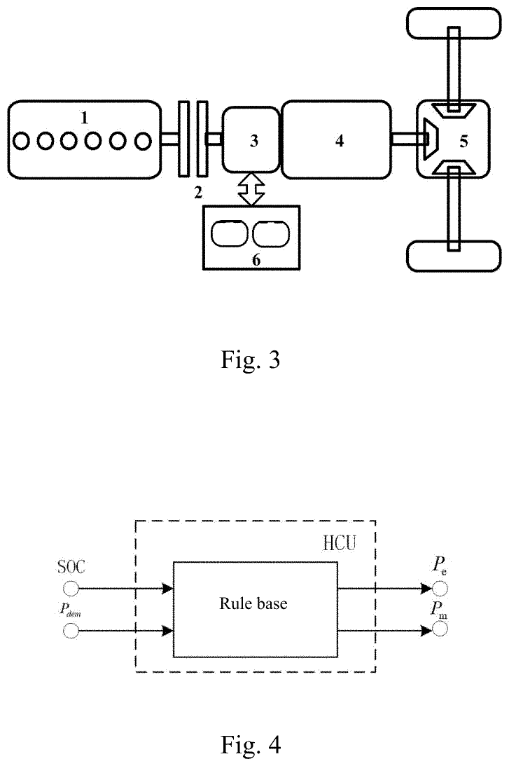

As shown in FIG. 3, a powertrain of the PHEB is illustrated, which comprises an engine 1, a clutch 2, a motor 3, a gearbox 4, a differential mechanism 5 and a battery 6, wherein the engine 1, the clutch 2, the motor 3, the gearbox 4 and the differential mechanism 5 are connected with each other in sequence, the motor 3 is connected with the battery 6. A control logic of the HCU inside the HEV and a corresponding specific rule base are shown in FIG. 4 and Table 1, respectively. It is able to be known from Table 1 that there are four important thresholds SOC_h, SOC_l, Pe_h and Pe_l that need to be optimized to improve fuel economy of the HEV. Moreover, combined with specific rules in Table 1, it is able to be seen that the prerequisite for improving the fuel economy of the HEV is to ensure the dynamic performance of the HEV and the safety of its own hardware.

TABLE 1
Rule-controlled rule base

| Input 1 | Input 2 | | Pₑ | Pₘ |
|---|---|---|---|---|
| SOC > SOC_h | P_{dem} ≤ 0 | | 0 | 0 |
| | P_{dem} < Pₘ_{_{—}}ₘₐₓ | | 0 | min (P_{dem} − Pₑ, |
| | | | | Pₘ_{_{—}}ₘₐₓ) |
| | P_{dem} ≥ | P_{dem} < Pₑ_{_{—}}ₕ | min (Pₑ_{_{—}}ₕ, | min (P_{dem} − Pₑ, |
| | Pₘ_{_{—}}ₘₐₓ | | Pₑ_{_{—}}ₘₐₓ) | Pₘ_{_{—}}ₘₐₓ) |
| | | Pₑ_{_{—}}ₗ ≤ P_{dem} ≤ | min (P_{dem}, | P_{dem} − Pₑ |
| | | Pₑ_{_{—}}ₕ | Pₑ_{_{—}}ₘₐₓ) | |
| | | P_{dem} < Pₑ_{_{—}}ₗ | min (Pₑ_{_{—}}ₗ, Pₑ_{_{—}}ₘₐₓ) | max (P_{dem} − Pₑ, |
| | | | | Pₘ_{_{—}}ₘᵢₙ) |

| | | | |
|---|---|---|---|
| SOC_l ≤ SOC ≤ | P_{dem} ≤ 0 | 0 | max (P_{dem}, |
| SOC_h | | | Pₘ_{_{—}}ₘᵢₙ) |
| | P_{dem} Pₑ_{_{—}}ₕ | min (Pₑ_{_{—}}ₕ, | min (P_{dem} − Pₑ, |
| | | Pₑ_{_{—}}ₘₐₓ) | Pₘ_{_{—}}ₘₐₓ) |
| | Pₑ_{_{—}}ₗ ≤ P_{dem} ≤ Pₑ_{_{—}}ₕ | min (P_{dem}, | P_{dem} − Pₑ |
| | | Pₑ_{_{—}}ₘₐₓ) | |
| | P_{dem} < Pₑ_{_{—}}ₗ | 0 | min (P_{dem}, |
| | | | Pₘ_{_{—}}ₘₐₓ) |
| SOC < SOC_l | P_{dem} ≤ 0 | 0 | max (P_{dem}, |
| | | | Pₘ_{_{—}}ₘᵢₙ) |
| | P_{dem} > Pₑ_{_{—}}ₕ | min (P_{dem}, | min (P_{dem} − Pₑ, |
| | | Pₑ_{_{—}}ₘₐₓ) | Pₘ_{_{—}}ₘₐₓ) |
| | Pₑ_{_{—}}ₗ ≤ P_{dem} ≤ Pₑ_{_{—}}ₕ | min (P_{dem}, | P_{dem} − Pₑ |
| | | Pₑ_{_{—}}ₘₐₓ) | |
| | 0.8 × Pₑ_{_{—}}ₗ ≤ P_{dem} ≤ Pₑ_{_{—}}ₗ | min (Pₑ_{_{—}}ₗ, Pₑ_{_{—}}ₘₐₓ) | min (Pₑ_{_{—}}ₗ, |
| | | | Pₑ_{_{—}}ₘₐₓ) |
| | P_{dem} < Pₑ_{_{—}}ₗ | 0 | min (P_{dem}, |
| | | | Pₘ_{_{—}}ₘₐₓ) |

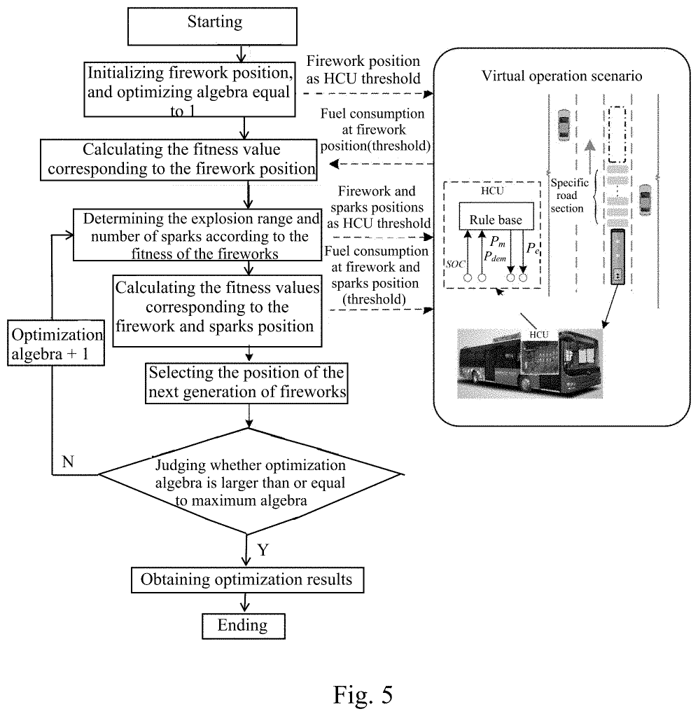

Of course, in the process of threshold optimization, it is also very important to adopt an efficient optimization algorithm to improve optimization efficiency. In the present invention, it is proposed to adopt the firework algorithm as the threshold optimization method in the HCU, which is a new intelligent optimization algorithm that has emerged in recent years. The firework algorithm simulates the process of firework display in real life, regards a certain display space as the parameter range, and takes the multi-dimensional position coordinates of randomly generated sparks as candidate values for the optimized parameter sequence. For example, the four-dimensional firework position coordinates (0.7, 0.5, 150, 98) are able to be understood that the thresholds SOC_h, SOC_l, Pe_h, and Pe_l are 0.7, 0.5, 150, 98, respectively. The firework algorithm has the characteristics of distributed and diffuse optimization, careful search in high-probability areas, and fast search in low-probability areas. FIG. 5 shows a specific optimization process for HCU thresholds. After the verification by related simulation experiments, it is proved that the firework algorithm is able to better fit the HCU parameter optimization work under the cyber-physical energy optimization control system.

In the process of parameter optimization of the firework algorithm, the following points need to be noted.

(1) The fitness value in FIG. 5 is the key to link the optimization algorithm with the vehicle control problem. Firstly, in the firework algorithm, the fitness value directly judges the quality of HCU parameters. The higher the fitness, the better the parameter is suitable for the current control work, and the easier it is to be preserved in the iterative evolution process. For vehicle control problems, the fitness value is directly related to the fuel consumption of the vehicle on a specific road section under the control of the HCU thresholds, and the two are in a negative correlation.

(2) Firework position (more than one firework) and spark position have the same status for finding the best position (multi-dimensional parameters). The difference is that the spark is usually randomly generated with the firework position as the center and a certain distance as the radius, so as to check whether there are better coordinate points around the firework position. The generation of sparks follows the principle that better fireworks produce more sparks in a smaller radius, while poor fireworks produce less sparks in a larger radius. The basis of this operation is that there is a certain continuity in the performance of the parameters, and the best parameters have a high probability of appearing near the better parameters. Therefore, this action is tantamount to rationally using the limited operation ability to quickly expand the global optimization.

(3) When selecting the position of the next generation of fireworks, the principle of the elite retention strategy will be followed, and the best firework or spark position of this generation will be reserved as one of the next generation of fireworks. At the same time, in order to effectively avoid the optimization falling into the local optimum, other fireworks are randomly generated in the current known positions.

What is claimed is:

1. A cyber-physical energy optimization control system for a hybrid electric vehicle (HEV), the system comprising an information layer which is configured to realize vehicle and road condition information collection, hybrid control unit (HCU) threshold optimization and threshold wireless update loading, and an optimized object plug-in hybrid electric bus (PHEB) as a physical layer, wherein:
the information layer comprises:
a global positioning system (GPS) and a geographic information system (GIS) configured to detect a real-time position of a vehicle and a road slope of the real-time position;
a traffic flow condition acquisition device which comprises multiple roadside speed detection cameras and multiple vehicles with a same route as an optimized vehicle, wherein the traffic flow condition acquisition device is configured to collect vehicle speed information which reflects traffic conditions; and
a remote monitoring center which is configured to collect information from the GPS/GIS and the traffic flow condition acquisition device on a road section to be optimized for constructing a vehicle model virtual operating platform for threshold optimization, and then quickly optimize HCU thresholds with the help of efficient optimization algorithms, and then obtain the best results, and then send and load the optimized HCU thresholds to a HCU before the optimized vehicle is about to arrive at the optimized road section.

2. A cyber-physical energy optimization control method for a hybrid electric vehicle (HEV) comprises steps of:
collecting a real-time position of an optimized HEV and road slope information of the real-time position, collecting speed information which reflects traffic conditions on a road section to be optimized, constructing a vehicle model virtual operating platform for threshold optimization through the collected information, quickly optimizing hybrid control unit (HCU) thresholds with a help of efficient optimization algorithms, obtaining best results, and finally sending and loading the optimized HCU thresholds to a HCU before the optimized vehicle is about to arrive at the optimized road section.

3. The cyber-physical energy optimization control method for the HEV according to claim 2, wherein the threshold optimization is achieved by firework algorithm.
